(19) United States
(12) Patent Application Publication
(10) Pub. No.: US 2018/0331533 A1
(43) Pub. Date: Nov. 15, 2018

(54) ELECTRICAL SYSTEM PROTECTION STRATEGY USING SLIP FREQUENCY CALCULATION

(71) Applicant: ABB Schweiz AG, Baden (CH)

(72) Inventor: Yang Lifeng, Macungie, PA (US)

(21) Appl. No.: 15/971,713

(22) Filed: May 4, 2018

Related U.S. Application Data
(63) Continuation of application No. PCT/US2016/061142, filed on Nov. 9, 2016.
(60) Provisional application No. 62/252,612, filed on Nov. 9, 2015.

(51) Int. Cl. H02H 7/06; H02H 1/00; G01R 23/02

(52) U.S. Cl. CPC H02H 7/06; G01R 23/02; H02H 1/0007

(57) ABSTRACT

An electrical system includes a plurality of synchronous electrical machines, and an electronic control unit structured to controllably trip a circuit breaking mechanism such as a relay coupling together the electrical machines. The control unit executes control logic to select trip options responsive to slip frequency between the synchronous electrical machines that is induced by a power swing.

### BACKGROUND

The present application relates generally to protection of electrical systems, and more particularly to controllably tripping a circuit breaking mechanism in a manner that is responsive to a slip frequency between electromagnetic machines during a power swing.

Synchronous machines such as electrical generators and motors, and related systems employing multiple coupled together synchronous machines are well-known and widely used, While there is ordinarily some allowance for minor differences and fluctuation in rotor angles amongst coupled-together machines, multiple electromagnetic machines feeding power to or receiving power from a common electrical grid or network are generally intended to operate within relatively small tolerances of a perfectly synchronous state. Changes in the electrical system such as faults, network changes due to line trip-outs, and disconnection or connection of a large load or of a generating plant generally requires the on-line synchronous machines to adjust and settle to a new stable condition. In some instances, power swings are lame enough that one or more of the synchronous machines can run out of step and lose synchronism. Such systems are typically equipped with relays or the like that arc structured to decouple certain machines or parts of the electrical system from certain other machines or parts of the electrical system. The separated parts of the electrical system can then eventually settle to stable states instead of causing a possible total system collapse, or the subparts can be shut down for service in a controlled manner.

Rather than relying on uncontrolled tripping of circuit breakers and the like, which has been observed to sometimes actually contribute to system collapses, a variety of different control strategies for blocking the trip function at least temporarily have been proposed and are in widespread use. Such known strategies suffer from various shortcomings relative to certain applications.

### DISCLOSURE

For the purposes of clearly, concisely and exactly describing exemplary embodiments of the invention, the manner and process of making and using the same, and to enable the practice, making and use of the same, reference will now be made to certain exeemplary embodiments, including those illustrated in the figures, and specific language will be used to describe the same. It shall nevertheless be understood that no limitation of the scope of the invention is thereby created, and that the invention includes and protects such alterations, modifications, and further applications of the exemplary embodiments as would occur to one skilled in the art.

### SUMMARY

One embodiment is a unique method for controllably and adaptively executing tripping functions in an electrical system responsive to a slip frequency between coupled together electrical machines.

### BRIEF DESCRIPTION OF THE DRAWINGS

FIG. 1 is a diagrammatic view of an electrical system according to one embodiment;

FIG. 2 is a chart of control characteristics according to one embodiment;

FIG. 3 is a flowchart illustrating example control logic according to one embodiment; and

FIG. 4 is a concept illustration comparing features of an adaptive trip strategy according to the present disclosure to a known strategy.

### DETAILED DESCRIPTION OF ILLUSTRATWE EMBODIMENTS

While the invention has been illustrated and described in detail in the drawings and foregoing description, the same is to be considered as illustrative and not restrictive in character, it being understood that only certain exemplary embodiments have been shown and described and that all changes and modifications that come within the spirit of the inventions are desired to be protected. It should be understood that while the use of words such as preferable, preferably, preferred or more preferred utilized in the description above indicate that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion andlor the entire item unless specifically stated to the contrary.

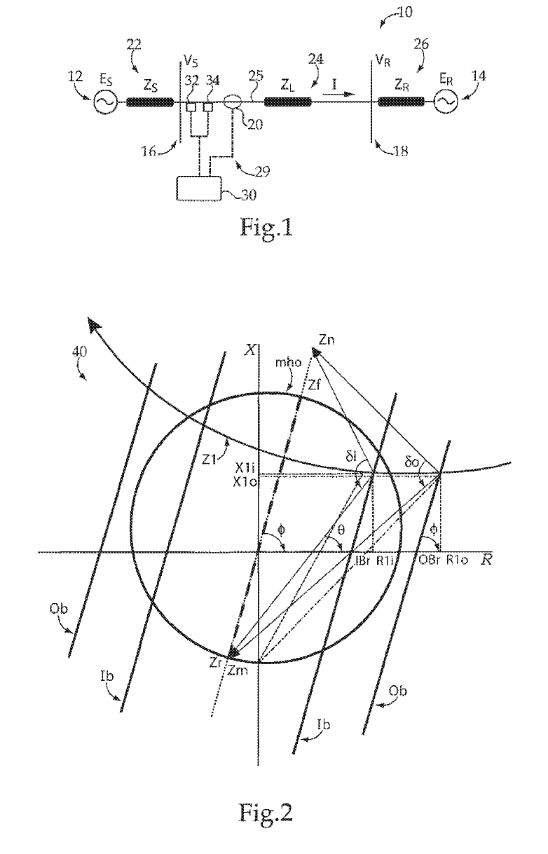

Referring to FIG. 1, there is shown diagrammatically an electrical system 10 in the nature of a two machine system having a first electrical generator 12 electrically coupled with a second electrical generator 14, with generators 12 and 14 feeding a first bus 16 and a second bus 18. A circuit breaking mechanism such as a relay 20 is coupled between electrical generators 12 and 14 and may be positioned between buses 16 and 18, Mechanism 20 can be a conventional protective relay, the operational aspects of which are generally well known, and including a computer so as to be programmable for purposes that will be apparent from the following description. In the illustrated embodiment, electrical system 10 may be understood as including a plurality of different subparts or subsystems including a first subsystem 22 that includes electrical generator 12 and having an impedance component Z a second electrical subsystem 26 that includes electrical generator 14 and having an impedance component Z_{R}, and a third subsystem 24 wherein relay 20 is disposed and having an impedance component Z_{L}. Rather than machine system, electrical system 10 might include any number of synchronous machines greater than two, structured for synchronous operation. System 10 might be or be a part of an electrical generating plant or an industrial facility, for instance.

While not specifically illustrated, each of generators 12 and 14 will be understood to include a rotor and a stator. During operation, it will generally be desirable for the rotors of generators 12 and 14 to rotate synchronously, at the same speed, and such that the phase angle between the two generators is maintained less than 90°. As discussed above, in various circumstances one or both of the rotor angles of generators 12 and 14 can be perturbed by retarding or accelerating forces caused by load changes, faults and other planned or unplanned disturbances. In some instances, where generators 12 and 14 become asynchronous, they can eventually settle back to a steady state or otherwise stable operating condition, In other instances, generators 12 and 14, or whatever other synchronous machines are part of system 10, cannot recover. As will be further apparent from the following description, the present disclosure provides unique strategies for tripping circuit breaking mechanism 20, and delaying or otherwise controllably tripping mechanism 20 so as to provide opportunities for system 10 to recover such that decoupling generators 12 and 14 is unnecessary, and also optimizing the manner and timing in which relay 20 is tripped or not tripped to ensure operation continues in a manner as smooth and predictable as possible.

To this end, system 10 further includes a control system 29 having an electronic control unit 30 including a computer and computer readable memory storing program instructions, and also a plurality of sensing mechanisms coupled with electronic control unit 30. In a practical implementation strategy, sensing mechanism 32 may he a voltage sensor and sensing mechanism 34 may be a current sensor, each structured to monitor amplitude of the subject property of voltage or current and provide data indicative thereof to electronic control unit 34. Control system 29 is thus structured to monitor the state of various electrical parameters of system 10, including voltage and current in circuitry 25 that couples buses 16 and 18 and thus machines 12 and IA. As further discussed herein, this enables electronic control unit 30 to calculate an impedance or an estimate of impedance that can be used to determine or estimate an impedance trajectory as fUrther discussed herein, for purposes of determining the manner in which mechanism 20 is to be operated, or not operated, to electrically decouple generators 12 and 14 from one another.

Referring now also to FIG.2, there is shown a chart 40 illustrating various control characteristics for controlling and operating system 10 according to the present disclosure. The ordinate represents Reactance “X”, whereas the abscissa represents Resistance “R”, Angle Φ is the line or system impedance angle, Z1 is an impedance trajectory, and Θ is the phase angle of Z1. It can also be seen that chart 40 includes a supervisory mho circle and left and right sets of double blinders, each including an outer blinder Ob and an inner blinder Ib. OBr represents an outer blinder resistance setting or value, IBr represents an inner blinder resistance setting, R1i and X1i are measured positive sequence resistance and reactance at the identified inner blinder, whereas R1o and X1o are measured positive sequence resistance and reactance at the outer blinder. δₒ is the angle at the crossing point of the outer blinder between two internal machine voltages, From FIG. 2, 6 is the angle between impedances Zₘ and Zₙ seen by two machines at M and N sides respectively, whereas δᵢ is an analogously defined angle at the impedance trajectory crossing point of the inner blinder IB. References herein to an angle defined by impedance trajectory, or an angle of the impedance trajectory generally refer to angles determined in a manner consistent with the foregoing description, although it is contemplated that one or more angles formed by the impedance trajectory relative to control characteristics other than double blinders might in some instances be exploited. Chart 40 can and likely will include additional control characteristics and zones which, if entered by the impedance trajectory Z1, will he interpreted to require various control actions such as relay tripping or out-of-step blocking. Those skilled in the art will be familiar with concentric circles, offset circles, polygons and potentially other features typically inside the supervisory mho circle which can indicate faults in a generator, faults in a transformer, or other phenomena that justify tripping the relay coupling electromagnetic machines in the electrical system independently of other control characteristics. For instance, where a generator fault, is indicated it will be unnecessary and perhaps undesirable to give that generator the opportunity to return to synchronism as such will typically not be possible. Such control characteristics can be used in chart 40 at the discretion Of the user and will depend upon the composition and application of electrical system 10 and user preferences.

It will thus be apparent that impedance trajectory Z1 will take on various forms depending on the nature of a power swing or fault occurring during operating electrical system 10. During normal or steady state operating conditions, impedance trajectory Z1 will tend to be out of view of chart 40, as the impedance will not be disturbed to the point of the trajectory traveling into the control characteristics shown in chart 40. Whereas certain known strategies have for some time relied upon observing characteristics of an impedance trajectory such as speed and/or acceleration of the trajectory, the present disclosure provides an altogether different strategy employing calculations of an estimate of slip frequency that eanbe advantageously used to decide what criteria are to be used for tripping relay 20. A frequency of slip induced by a power swing in the system relates to speed of the impedance change, thus where two electromagnet machines have a slip frequency of 1 Hz their rotor angles will be changing relative to one another at slower rate than where the two machines have a slip frequency of 2 Hz, and so on. The present disclosure exploits this phenomenon and the generally proportional relationship between slip frequency and speed of a power swing to determine whether tripping should take place right away or after a delay. Another way to understand these principles is that the present disclosure enables a controller to deter mine the nature of a power swing, and assert an appropriate trip mode based upon the speed of the power swing as indicated by the slip frequency. A function or routine according to the asserted trip mode is tailored to the power swing, and is thus initiated or called responsive to the slip frequency and appropriate actions such as outputting a trip command at an appropriate time taken. These principles will typically, although not exclusively, he applied in the context of so-calld out-of-step blocking. Thus, where conditions otherwise exist that might otherwise autonomously trip relay 20, electronic control unit 30 can controllably trip relay 20 in a manner considered unlikely to damage system 10 or produce widespread consequences.

For purposes of calculating slip frequency, or more particularly calculating a value indicative of slip frequency, assuming positive sequence voltage and current are readily available, positive sequence impedance Z1 can be calculated as follows:

$$R 1 + j \cdot X 1 = \frac{( {V}_{1 r} \cdot {I}_{1 r} + {V}_{1 i} \cdot {I}_{1 i} ) + j \cdot ( {V}_{1 i} \cdot {I}_{1 r} - {V}_{1 r} \cdot {I}_{1 i} )}{( {I}_{1 r} \cdot {I}_{1 r} + {I}_{1 i} \cdot {I}_{1 i} )}$$

$$Z 1 = \sqrt{R {1}^{2} + X {1}^{2}}$$

$$θ = {tan}^{- 1} ( \frac{X 1}{R 1} )$$

Swing angles at the outer and inner blinders can be estimated using the measured impedances and reverse reach setting, Those skilled in the art will appreciate that the reverse reach setting relates to impedance of the generator or other electromagnetic machines and is generally a setting available from the manufacturer or user specified. For the swing angles:

$${δ}_{o} = 2 \cdot {tan}^{- 1} ( \frac{X {1}_{o} + \vert {Z}_{r} \vert}{R {1}_{o}} )$$

$${δ}_{i} = 2 \cdot {tan}^{- 1} ( \frac{X {1}_{i} + \vert {Z}_{r} \vert}{R {1}_{i}} )$$

Where R1₀ and X1₀, and are as specified above. For monitoring purposes, frequency slip Fₛₗᵢₚ can be obtained as early as Z1 crosses the inner blinder when a swing or out of step block as further discussed herein is declared, and can be calculated as follows:

$${f}_{slip} = \frac{{δ}_{i} - {δ}_{o}}{2 \cdot π \cdot {T}_{ol}}$$

Where Tₒᵢ is the time for Z1 to travel from the outer blinder to the inner blinder.

When slip frequency is calculated, various tripping options are available. As further discussed below, when a first trip option TOWO (trip on way-out) is selected, a breaker open time (BOT), if known, can be incorporated to optimize breaker trip time when a trip command is issued. An ideal time for a breaker to be tripped to interrupt current is typically where swing angle approaches zero. Those skilled in the art will be familiar with the desirability of tripping a breaker at approximately zero voltage so as to minimize the likelihood of flashover or arcing. Suppose swing angle exiting the outer blinder, that is when impedance trajectory Z1 exits the outer blinder, is δₒ, then an out of step (OST) trip delay (T_{od}) can be set such that:

$${T}_{od} = \frac{{δ}_{o} - 2 \cdot π \cdot {f}_{slip} \cdot ( BOT + {T}_{r} )}{2 \cdot π \cdot {f}_{slip}}$$

Where Tᵣ is the time from the relay, or more particularly electronic control unit coupled with the relay, issuing a trip command to the time when the breaker receives the command. BOT can be a user specified breaker open time. δₒ, in the above equation can be the estimation when impedance trajectory Z1 enters the outer blinder from outside the characteristic as described before, or it can be more accurately estimated as follows:

δₒ=π−2·π·fₛₗᵢₚ·T_{co}

Where T_{co} is the time that trajectory Z1 travels from the center impedance line to the outer blinder on the opposite side, left side in the case of chart 40, Therefore:

$${T}_{od} = \frac{1 - 2 \cdot {f}_{slip} \cdot ( {T}_{co} + BOT + {T}_{r} )}{2 \cdot {f}_{slip}}$$

Using conventional trip approaches, it is typically predetermined as to whether so called TOWO or trip on way-in (TOW I) is used. The present disclosure provides additional possibilities and improves over conventional strategies and exploits the calculation of slip frequency to provide an adaptive approach to Out of step condition management, not needing to be predetermined and allowing an out of step function to automatically determine a trip option between TOWO and TOWI.

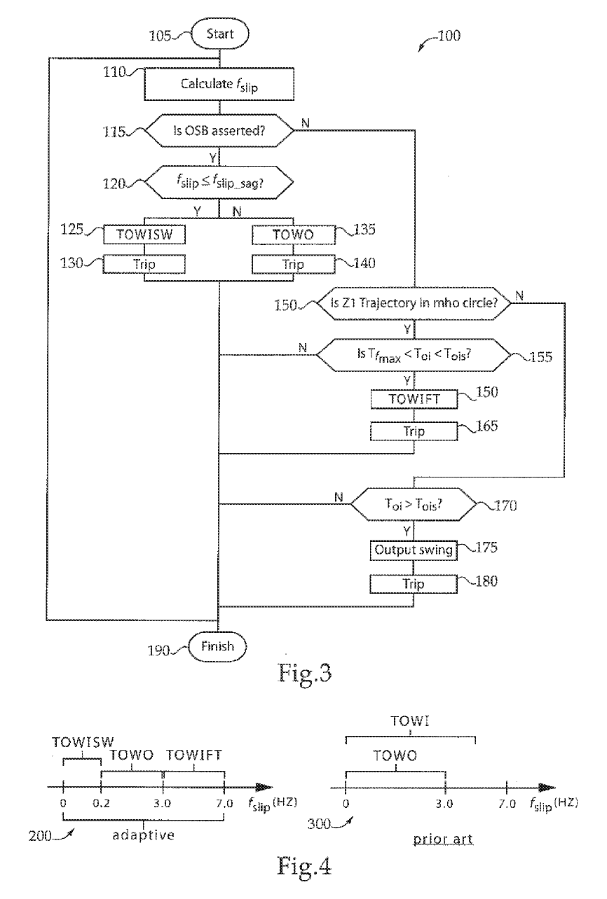

Referring also now to FIG. 3, there is shown a flowchart 100 illustrating example control logic flow according to one embodiment. The logic starts/function enters at block 105, and advances to block 110 to calculate slip frequency. From block 110, the logic advances to block 115 to query whether out of step blocking is asserted. As will be familiar to those skilled in the art, out of step blocking is asserted typically where conditions exist that might trigger a circuit breaking mechanism such as relay 20, but is desirable to inhibit or forego operation of the circuit breaking mechanism at least until certain specified criteria are satisfied. If out of step Hocking or OSB is asserted, the logic may advance, to block 120 where fUrther processing commences, if OSB is not asserted, the logic may advance to block 150.

In a practical implementation strategy, OSB may be asserted when an out of step condition exists, and a time for impedance travel from the first outer blinder to the inner blinder, on the right in FIG. 2, can be used for this determination, If the time for the impedance travel is greater than a specified out of step time for an unstable swing, and impedance trajectory Z1 enters the niho circle, an out of step condition exists and out of step blocking is asserted. If these conditions arc not met, OSB may not he asserted. In general terms, if OSB is asserted it means the swing is unstable. Assertion of OSB, and the underlying calculations, do not determine how slow the swing is, however. Since impedance is already in the mho circle at this point, voltage may be lowered to such a low level that the system tolerance for such conditions can be exceeded. According to the present disclosure., a calculation may be performed to determine whether that low voltage tolerance condition is exceeded. In particular, a user specified setting V_dip_time_allowed, a predefined voltage sag time that the system can tolerate, can be used to determine an equivalent or corresponding slowest slip frequency that is allowed. The following equation illustrates the slowest slip frequency calculation:

$${f}_{slip \_ sag} = \frac{( π - {δ}_{o} )}{π \cdot V\_Dip \_Time \_Allowed}$$

If slip frequency is less than or equal to the slowest slip frequency, fₛₗᵢₚ≤fₛₗᵢₚ_{_}_{sag}, then trip on the way in slow (TOWISW) is selected at block 125. It will be understood that electronic control unit 30 is performing a comparison of the calculated slip frequency or value indicative thereof with the stored slip frequency or corresponding value. If slip frequency is not less than or equal to the slowest slip frequency, TOWO is selected at block 135. From block 125, the logic may advance to block 130 to trip relay 20 typically as quickly as possible, but also potentially according to some user specified predetermined criteria. At block 135, TOWO is selected and a number of slips or other predefined criteria that is typically user specified can be used to trigger a trip at block 140. Accordingly, a timing of the trip can be determined responsive to slip frequency as per block 120 and the split paths thereafter. From either of blocks 130 or 140, the logic may advance to finish at block 190, or may loop back to execute again as shown in FIG. 3.

If OSB is not asserted, as noted above from block 115 the logic may advance to block 150 to query whether 71 trajectory is inside the niho circle. In this instance, trip mode may be understood as selected based upon impedance trajectory location. If trajectory Z1 is inside the mho circle, and Z1 travel time between the outer and inner blinders Tₒᵢ is less than an out of step time setting Tₒᵢₛ but greater than a predetermined time T_{fmax}, at block 155 the logic may advance to block 160 to select trip on the way in fast (IDWIFT). The values of Tₒᵢₛ and T_{fmax}, may be user specified, and determined empirically. T_{fmax} can be understood as a time interval that is based on a speed of a power swing above which a fault is determined. If the answer is yes at block 155, this can be taken to mean a severe swing appears to be occurring. From block 160, the logic may advance to block 165 to trip, and then to finish or loop back again at block 190. If, at block 150, Z1 is not within the mho circle, the logic may advance to block 170 to query whether Tₒᵢ is greater than Tₒᵢₛ. If no, the logic may advance to block 190 to Finish or loop back. If yes, from block 170 the logic may advance to block 175 to select the output swing. In this case, with Z1 outside the rnho circle and travel time Tₒᵢ greater than the out of step time setting Tₒᵢₛ, it can be taken to mean the swing center is far away and the local system is not likely in immediate danger. Output swing is thus asserted and a number of swings that is predefined can be counted, and a swing zone trip issued if enabled at block 180. From block 180, the logic can advance to block 190 or loop back.

From the foregoing description, it can be seen that exploiting slip frequency can provide a number of control possibilities that are not available with the use of conventional techniques. Referring also now to FIG. 4, there is shown a first illustration of functions according to the present disclosure applied along a continuum of slip frequencies, in comparison with a second illustration 300 illustrating functions according to a prior art strategy applied along the same slip frequency continuum. In the case of the present disclosure, it can be seen that TOWISW can be applied to a defined and exclusive range of slip frequency, fOr example from. about 0 Hz to about 0.2 Hz. TOWO can be applied, for example, from a slip frequency of about 0.2 Hz to a slip frequency of about 3.0 Hz, and. TOWIFT can be applied from a slip frequency of about 3.0 Hz to about 7.0 Hz. In the prior art technique, TOWI of only one form and TOWO can be applied only up to a slip frequency somewhere between about 3.0 Hz and about 7.0 Hz. As illustrated, the present disclosure provides the advantage of extending slip frequency range so that tripping can detect a fast swing, faster than what can be detected according to the prior art strategy illustrated. In other words, what would likely happen employing the prior art strategies shown, is that above the 3.5 or 4.0 slip frequency, everything faster would be considered a fault and out of step blocking and controlled tripping not available. In addition, the adaptive approach of the present disclosure also enables speeding up of tripping for a very slow swing to avoid system damage from a prolonged voltage sag whereas with conventional techniques TOWO would have been applied, resulting sometimes in a delay sufficient to result in system damage.

The present description is for illustrative purposes only, and should not be construed to narrow the breadth of the present disclosure in any way. Thus, those skilled in the art will appreciate that various modifications might be made to the presently disclosed embodiments without departing from the full and fair scope and spirit of the present disclosure. Other aspects, features and advantages will he apparent upon an examination of the attached drawings and appended claims.

What is claimed is:

1. A method of protecting an electrical system comprising:
receiving data indicative of an angle of an impedance trajectory defined by an impedance in the electrical system during a power swing;
calculating a value indicative of a frequency of a slip between a first and a second electromagnetic machine M the electrical system that is induced by the power swing, responsive to the data;
asserting a trip mode responsive to the calculated value; and
outputting a trip command to a circuit breaking mechanism in the electrical system according to the asserted trip mode so as to decouple the first and the second electromagnetic machines.

2. The method of claim 1 further comprising receiving data indicative of a second angle of the impedance trajectory, and wherein the calculating includes calculating the value responsive to the data indicative of the second angle.

3. The method of claim 2 wherein the first angle and the second angle arc defined by the impedance trajectory at an outer blinder crossing point and an inner blinder crossing point, respectively.

4. The method of claim 3 wherein the calculating includes calculating the frequency via the equation:
$${f}_{slip} = \frac{{δ}_{i} - {δ}_{o}}{2 \cdot π \cdot {T}_{oi}}$$
where Tₒᵢ is a travel time of the impedance trajectory from the outer blinder to the inner blinder.

5. The method of claim 1 wherein the first and second electromagnetic machines include a first and a second electrical generator, and the slip frequency is determined by a difference in rotation frequency between rotors in the first and second electrical generators.

6. The method of claim 1 wherein the asserting of a trip mode includes asserting one of a trip on-the-way-in mode and a trip on-the-way-out mode, and the outputting further includes outputting the trip command at an earlier time if the trip on-the-way-in mode is asserted and outputting the trip command at a later time if the trip on-the-way-out mode is asserted.

7. The method of claim 6 further comprising comparing the calculated frequency value with a stored slip frequency value corresponding to an allowable voltage sag time, and asserting the trip on the way in function if the stored slip frequency is less than the stored slip frequency sag time.

8. An electrical system protection mechanism comprising:
a circuit breaking mecha.nisna positionable within a circuit coupling a first electromagnetic machine to a second electromagnetic machine;
sensing mechanisms structured to monitor parameters of the electrical system indicative of impedance;
an electronic control unit coupled with the sensing mechanisms and in control communication with the circuit breaking mechanism, and the electronic control unit being structured to determine an angle of an impedance trajectory defined by the impedance during a power swing, and to calculate a value indicative of a frequency of a slip between the first and second electromagnetic machines that is induced by the power swing, responsive to the determined angle; and
the electronic control unit further being structured to assert a trip mode responsive to the calculated value, and to output a trip command to the circuit breaking mechanism according to the asserted trip mode so as to decouple the first and the second electromagnetic machines.

9. The mechanism of claim 8 wherein the circuit breaking mechanism includes a protective relay.

10. The mechanism of claim 8 wherein the electronic control unit is further structured to determine a second angle of the impedance trajectory, and to calculate the value responsive to the first angle and the second angle.

11. The mechanism of claim 10 wherein the electronic control unit is further structured to calculate the value responsive to a travel time of the impedance trajectory from an outer blinder having a first resistance setting to an inner blinder having a second resistance setting.

12. The mechanism of claim 8 wherein the electronic control unit is further structured to compare the calculated value with a stored slip frequency value corresponding to an allowable voltage sag time, and to assert a trip on-the-way-in mode if the calculated slip frequency is less than or equal to the stored slip frequency sag time.

13. The mechanism of claim 12 wherein the electronic control unit is further structured to assert a trip on-the-way-out mode if the calculated slip frequency is greater than the stored slip frequency sag time.

14. The mechanism of claim 13 wherein the electronic control unit is further structured to determine a time delay in outputting the trip command in the trip on-the-way-out mode based in part on the slip frequency.

15. An electrical power system comprising:
a plurality of electromagnetic machines;
electrical circuitry coupling together the plurality of electromagnetic machines;
a circuit breaking mechanism coupled with the circuitry and structured to decouple two of the plurality of electromagnetic machines; and
an electronic control unit in control communication with the circuit breaking mechanism, and being structured to determine an angle of an impedance trajectory defined by an impedance in the electrical circuitry during a power swing, and to determine a frequency of a slip between the plurality of electromagnetic machines that is induced by the power swing, responsive to the determined angle;
the electronic control unit further being structured to output a trip command to the circuit breaking mechanism at a timing that is based at least in part on the determined frequency.

16. The system of claim 15 wherein the electronic control unit is further structured to determine the impedance responsive to data indicative of voltage amplitude and current amplitude in the electrical system.

17. The system of claim 15 wherein the electronic control unit is further structured to determine a second angle of the impedance trajectory, and to calculate the value indicative of the slip frequency based on both of the first angle and the second angle and a travel time of the impedance trajectory.

18. The system of claim 17 wherein the first angle and the second angle are defined by the impedance trajectory at an outer blinder crossing point and an inner blinder crossing point,point, respectively, where the outer and inner blinders are located at levels of resistance along the impedance trajectory.

19. The system of claim 18 wherein the electronic control unit is structured to calculate the frequency via, the equation:
$${f}_{slip} = \frac{{δ}_{i} - {δ}_{o}}{2 \cdot π \cdot {T}_{oi}}$$
where Tₒᵢ is a travel time of the impedance trajectory from the outer blinder to the inner blinder.
